(19) United States
(12) Patent Application Publication
(10) Pub. No.: US 2022/0336280 A1
(43) Pub. Date: Oct. 20, 2022

(54) METHOD OF MANUFACTURING MICROELECTRONIC DEVICES AND RELATED MICROELECTRONIC DEVICES, TOOLS, AND APPARATUS

(71) Applicant: Micron Technology, Inc., Boise, ID (US)

(72) Inventors: Brandon P. Wirz, Boise, ID (US); Andrew M. Bayless, Boise, ID (US)

(21) Appl. No.: 17/231,313

(22) Filed: Apr. 15, 2021

(51) Int. Cl. H01L 21/78; H01L 23/544; H01L 21/326; H01L 21/67

(52) U.S. Cl. CPC H01L 21/78; H01L 23/544; H01L 21/326; H01L 21/67092; H01L 2223/5446

(57) ABSTRACT

Microelectronic devices may include an active surface and a side surface. The side surface may include a first portion having a reflective surface and a second portion having a non-reflective surface. The reflective surface may be formed by depositing a conductive material in trenches formed in material of the wafer along streets between the microelectronic devices on a wafer. The conductive material may be heated. The wafer may be cooled after the conductive material is heated fracturing the wafer along the streets and separating the microelectronic devices.

### TECHNICAL FIELD

Embodiments of the disclosure relate to a method of manufacturing microelectronic devices. Specifically, some embodiments relate to methods of separating semiconductor wafers into microelectronic devices, and to related microelectronic devices, tools, and apparatus.

### BACKGROUND

As performance of electronic devices and systems increases, there is an associated demand for improved performance of microelectronic components of such systems, while maintaining or even shrinking the form factor (i.e., length, width and height) of a microelectronic device or assembly. Such demands are often, but not exclusively, associated with mobile devices and high-performance devices. To maintain or reduce the footprint and height of an assembly of components in the form of microelectronic devices (e.g., semiconductor die), three-dimensional (3D) assemblies of stacked components equipped with so-called through silicon vias (TSVs) for vertical electrical (i.e., signal, power, ground/bias) communication between components of the stack have become more common, in combination with the reduction in component thickness, as well as employment of preformed dielectric films in the bond lines (i.e., spaces between stacked components) to reduce bond line thickness while increasing bond line uniformity. Such dielectric films include, for example, so-called non-conductive films (NCFs), and wafer level underfills (WLUFs), such terms often being used interchangeably. While effective in reducing height of 3D microelectronic device assemblies, the reduction in thickness of microelectronic devices, for example semiconductor dice, to about 50 μm or less (e.g., 30 μm, 20 μm) increases device fragility and susceptibility to cracking under stress, particularly compressive (i.e., impact) stress and bending stress. Decreasing bond line thickness may also exacerbate susceptibility to damage to such extremely thin microelectronic devices, as the thin dielectric material (e.g., NCF) in the bond lines may no longer provide any cushioning effect or ability to accommodate particulate contaminants in the bond lines when, for example, a device is stacked on another device to form a 3D assembly. Non-limiting examples of microelectronic device assemblies including stacked microelectronic devices which may suffer from stress-induced cracking include assemblies of semiconductor memory dice, alone or in combination with other die functionality (e.g., logic) include so-called high bandwidth memory (HBMx), hybrid memory cubes (HMCs), and chip to wafer (C2W) assemblies.

### BRIEF DESCRIPTION OF THE DRAWINGS

While the specification concludes with claims particularly pointing out and distinctly claiming embodiments of the present disclosure, the advantages of embodiments of the disclosure may be more readily ascertained from the following description of embodiments of the disclosure when read in conjunction with the accompanying drawings in which:

FIG. 1 illustrates a schematic view of a stacked microelectronic device;

FIGS. 2A and 2B are enlarged views of a stacked microelectronic device showing an impaired electrical connection due to the presence of particulate contaminants;

FIGS. 3A and 3B illustrate electron microscope images of a microelectronic device showing damage caused by particulate contaminants;

FIG. 4 illustrates a perspective view of a wafer with microelectronic devices formed thereon;

FIGS. 5-13 illustrate cross-sectional views of the wafer of semiconductor dice illustrated in FIG. 4 during dicing process steps;

FIG. 14A illustrates a top view of a the wafer of semiconductor dice illustrated in FIGS. 4-13;

FIG. 14B illustrates an enlarged view of a section of the wafer of semiconductor dice illustrated in FIG. 14A;

FIGS. 15 and 16 illustrates a cross-sectional view of the wafer of semiconductor dice illustrated in FIGS. 4-14B during dicing process steps;

FIGS. 17 and 18 illustrate cross-sectional views of the wafer of semiconductor dice illustrated in FIGS. 4-12 during dicing process steps;

FIG. 19A illustrates a side view of a semiconductor die in accordance with one or more embodiments of the present disclosure;

FIG. 19B illustrates a top view of the semiconductor die illustrated in FIG. 19A; and

FIG. 20 illustrates a side view of a stack of semiconductor dice in accordance with one or more embodiments of the present disclosure.

### DETAILED DESCRIPTION

The illustrations presented herein are not meant to be actual views of any particular microelectronic device, assembly, or component thereof, but are merely idealized representations employed to describe illustrative embodiments. The drawings are not necessarily to scale.

As used herein, the term “substantially” in reference to a given parameter means and includes to a degree that one skilled in the art would understand that the given parameter, property, or condition is met with a small degree of variance, such as within acceptable manufacturing tolerances. For example, a parameter that is substantially met may be at least about 90% met, at least about 95% met, at least about 99% met, or even at least about 100% met.

As used herein, relational terms, such as “first,” “second,” “top,” “bottom,” etc., are generally used for clarity and convenience in understanding the disclosure and accompanying drawings and do not connote or depend on any specific preference, orientation, or order, except where the context clearly indicates otherwise.

As used herein, the term “and/or” means and includes any and all combinations of one or more of the associated listed items.

As used herein, the terms “vertical,” “horizontal,” and “lateral” refer to the orientations as depicted in the figures.

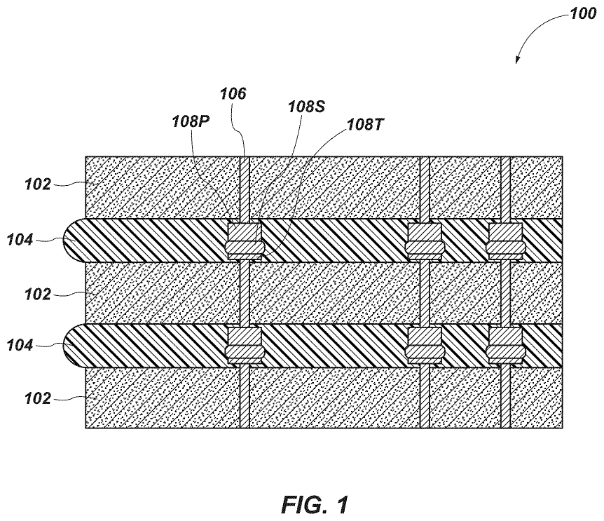

FIG. 1 illustrates a microelectronic device 100. The microelectronic device 100 may include multiple semiconductor dice 102 arranged in a stack. A dielectric film 104, such as a non-conductive film (NCF) or a wafer level underfill (WLUF) may be positioned between each of the semiconductor dice 102. The microelectronic device 100 may include through silicon vias (TSVs) 106 aligned with contacts in the form of conductive pillars 108P optionally capped with solder material 108S and bonded to terminal pads 108T of adjacent semiconductor dice 102 to provide electrical contacts between the semiconductor dice 102 and/or through the stack of dice. For example, the TSVs 106 and aligned contacts may provide power, ground/bias, and signal connections.

The height of the microelectronic device 100 may be reduced by reducing a thickness of the semiconductor dice 102 and/or the dielectric film 104. Reducing the thickness of the semiconductor die 102 may cause a semiconductor die 102 to be more fragile and susceptible to damage in the form of microcracking, cracking and edge chipping during the picking and stacking processes as described in further detail below. Reducing the thickness of the dielectric film 104 may reduce the ability of the dielectric film 104 to provide any cushioning effect or the ability to accommodate particulate contaminants in the bond lines without damage to the semiconductor dice 102. For example, contaminant particles between the semiconductor dice 102 may cause one or more of the semiconductor die 102 to bend, crack and/or break due to stress concentrations caused by the presence of the contaminant particles when a semiconductor die 102 is picked from a carrier, transferred to a bond tip, or stacked on another semiconductor die 102 or substrate. In some embodiments, contaminant particles between the semiconductor die 102 may substantially prevent one or more of the conductive pillars108P from making electrical contact with an aligned terminal pad108T.

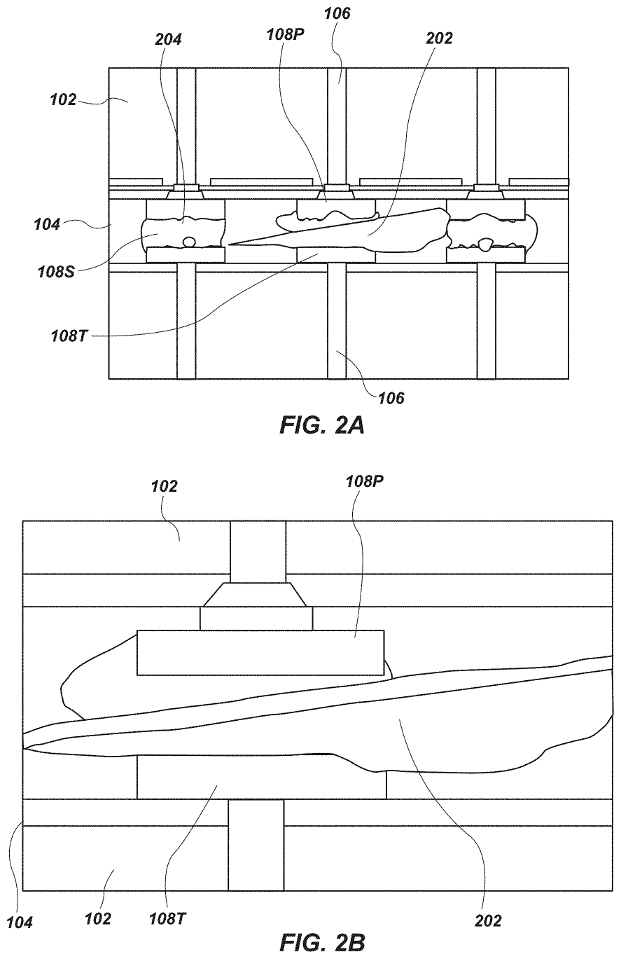

FIGS. 2A and 2B illustrate enlarged views of an impaired electrical connection point between two semiconductor dice 102 due to the presence of a particulate contaminant. As illustrated in FIGS. 2A and 2B a particle 202, such as a particle of organic (e.g., polymer) material or inorganic (e.g., silicon) material, may be present in the bond line between the semiconductor dice 102. The bond line between the semiconductor dice 102 may include the dielectric film 104 and solder material 108S configured to provide an electrical connection between the conductive pillars 108P and aligned terminal pads 108T of the adjacent semiconductor dice 102. In some cases, the particle 202 may be positioned between one or more sets of conductive pillars108P and terminal pads108T as shown in FIGS. 2A and 2B, such that the particle 202 may interrupt or displace the solder materia1108S. In assemblies where diffusion bonding of conductive pillars 108P directly to terminal pads 108T is employed or where thermo compression bonding is used to melt solder materia1108S as depicted in FIGS. 2A and 2B to bond the conductive pillars 108P to the terminal pads 108T, particle 202 may prevent mutual contact thereof, resulting in an open circuit.

The particle 202 may cause the associated microelectronic device 100 to fail. For example, the particle 202 may substantially prevent an operable electrical connection between at least one conductive pillar 108P and terminal pad 108T. In some cases, the particle 202 may allow part of the solder material 108S to form a connection between a portion of the conductive pillar 108P and terminal pad 108T, while substantially preventing a connection between another portion of the conductive pillar 108P and terminal pad 108T. The partial connection between the conductive pillar 108P and terminal pad 108T may pass initial testing of the assembly but exhibit increased resistance, creating heat that may cause a premature failure of the connection in operation after incorporation of the microelectronic device in a system (e.g., computer, server, mobile device). In some cases where extremely tight pitches (i.e., lateral spacing) between connections are employed, the particle 202 may displace solder material 108S create an electrical connection between two laterally adjacent pairs of contacts, causing a short.

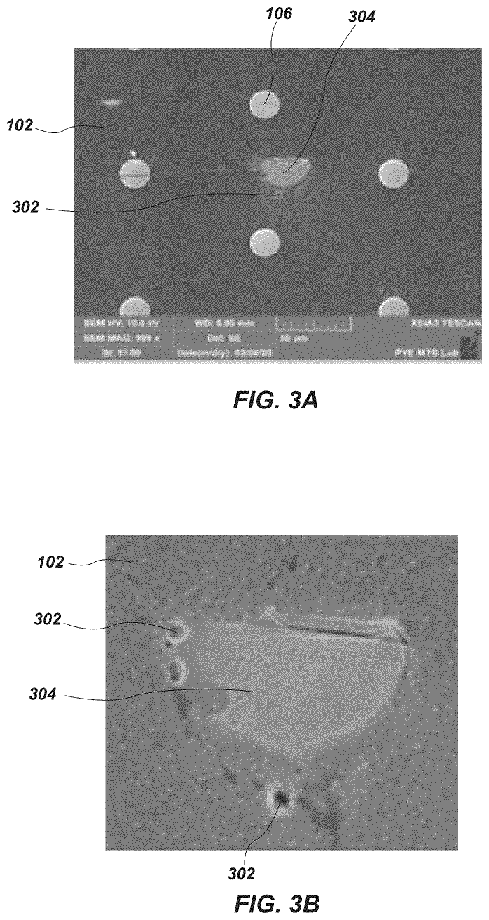

FIGS. 3A and 3B illustrate views of a semiconductor die 102 with damage resulting from the presence of contaminant particles 302 in the bond line between semiconductor dice 102. As described above, reducing the thickness of the semiconductor die 102 may cause the semiconductor die 102 to be more fragile and reducing the thickness of the dielectric film 104 may reduce the ability of the dielectric film 104 to provide any cushioning effect or the ability to accommodate particulate contaminants in the bond lines. As the semiconductor dice 102 are stacked and pressed together, a contaminant particle 302, in the space between the semiconductor dice 102, may cause a portion of the semiconductor die 102 to lift and/or break, creating a broken portion 304 (e.g., delaminated portion, crack, chip, etc.) of the semiconductor die 102.

As the dielectric film 104 thickness is reduced, even extremely small contaminant particles 302 may cause microcracks or even cracks in the semiconductor die 102. For example, in the context of near-zero bondline (NZB) assemblies, for example using hybrid bonding techniques currently under development, the dielectric film 104 may comprise a silicon oxide or extremely thin polymer, allowing a bond line thickness of less than about 1 micrometer (μm), such as less than about 500 nanometers (nm). With a bond line of less than about 1 μm, contaminant particles 302 in a similar size range, such as contaminant particles 302 between about 600 nm and about 1 μm may cause concentration of stresses between adjacent semiconductor dice 102, resulting in cracking or microcracking.

The broken portion 304 may render the associated semiconductor die 102 useless. Because the stack of semiconductor dice 102 may not experience substantial compressive forces until the entire stack is assembled and thermocompression bonded, a semiconductor die 102 may not crack until after the stack of semiconductor dice 102 is assembled and bonded. Thus, the broken portion 304 may render useless the entire microelectronic device 100 comprising the stack of semiconductor dice 102. As a result, the presence of contaminant particles in bond lines of a stack of semiconductor dice 102 may cause significant yield losses during the production of microelectronic devices using qualified, known good dice (KGD) due to post-assembly structural damage caused by the contaminant particles, as well as electrical connection problems caused by the contaminant particles.

Reducing and/or eliminating the introduction of particles to surfaces of the semiconductor dice during the manufacturing process may increase a yield of microelectronic devices and reduce the potential for so-called “infant mortality” (i.e., premature failure) of such microelectronic devices and of systems incorporating same. Increasing the yield of microelectronic devices and reducing infant mortality may decrease the costs associated with producing the microelectronic devices and systems, and allow a longer operational life. These reduced cost may similarly reduce costs of associated electronic products, such as mobile phones, computers, laptops, etc.

Some embodiments of the present disclosure may include a method of manufacturing a microelectronic device. The method may include forming one or more microelectronic devices on an active surface of a wafer. The method may further include removing material from the wafer in streets between the one or more microelectronic devices to form a recessed region in the streets. The method may also include depositing a metal material on one or more sides of the recessed region in the streets. The method may further include heating the metal material on the one or more sides of the recessed region in the streets. The method may also include cooling the wafer after heating the metal material. The method may further include fracturing the wafer along the streets through thermoshock induced by cooling the wafer.

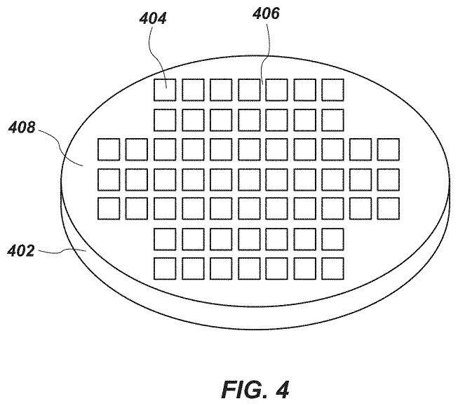

During the manufacturing process semiconductor dice may be formed in an array on a wafer. FIG. 4 illustrates a perspective view of an array of unsingulated dice 404 (i.e., die locations) arranged on an active surface 408 of a wafer 402. Each die 404 may be separated from the surrounding dice 404 by streets 406. A width of the streets 406 may define a distance between the dice 404. The width of the street 406 may be defined by the width required by the tool or process used to singulate (e.g., dice, cut, separate) the wafer 402 into individual dice 404. Reducing the width of the streets 406 may enable a larger number of dice 404 to be formed on each wafer 402, which may increase the yield for each wafer 402.

Some embodiments of the present disclosure may include a method of separating microelectronic devices from a wafer. The method may include removing material from the wafer in streets between the microelectronic devices to form trenches in the streets. The method may further include depositing a metal material on one or more surfaces of the trenches. The method may also include heating the wafer by inducing an electrical current in the metal material on the one or more surfaces of the trenches. The method may further include cooling the wafer after heating the wafer. The method may also include fracturing the wafer along the streets through thermoshock induced by cooling the wafer.

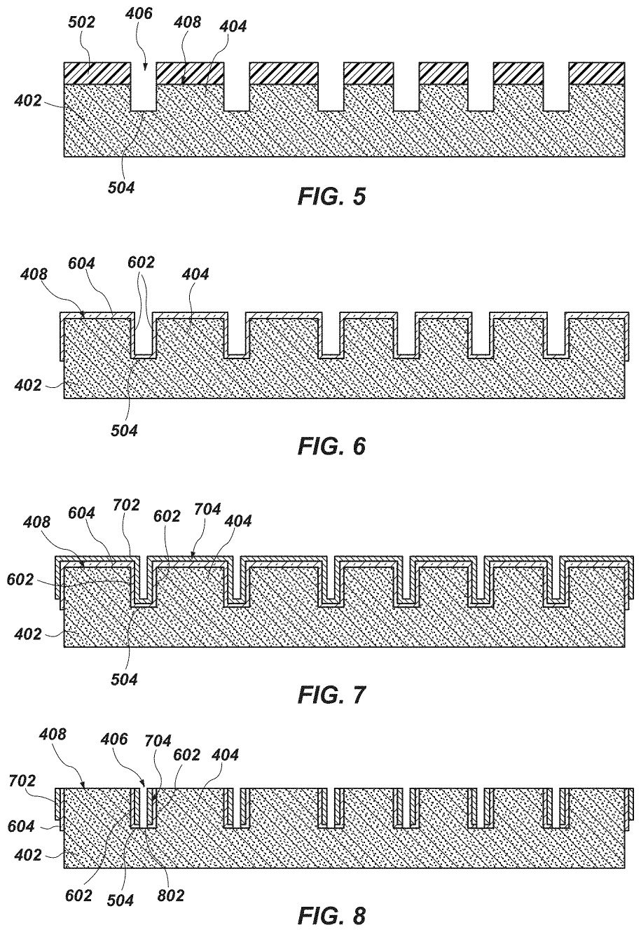

FIGS. 5-17 illustrate process acts of singulating, or dicing, a wafer, such as wafer 402 along the streets 406 to separate the array of dice 404 into individual dice 404. After the dice 404 are formed on the active surface 408 of the wafer 402, material may be removed from the streets 406 to form a trench 504 in the active surface 408 of the wafer 402, as illustrated in FIG. 5. The material may be removed through an etching process, such as a dry etching process (e.g., reactive ion etching, also termed plasma etching), or laser etching.

For example, the active surface 408 of the wafer 402 may be covered by a mask 502, such as a photo mask. The wafer 402 may then undergo a dry etching process. The dry etching process may be configured to remove material from the active surface 408 of the wafer 402 in areas defined by openings in the mask 502. The dry etching process may be anisotropic and substantially directional, such that material removal may be substantially coincident with material aligned with openings in the mask 502 and may effect high aspect ratio (i.e., length to width ratio) trenches 504 exhibiting substantially vertical sidewalls. The width of the trenches 504 may be less than about 80 μm, such as between about 10 μm and about 40 μm.

Dry etching processes may be configured to remove material at a specified rate. The specified rate may be defined by the power applied, the type of ions used, the material being removed, the temperature of the material, the ambient temperature, etc. Thus, a depth of the trench 504 may be determined by the amount of time that the wafer 402 undergoes the dry etching process under given etch parameters. In embodiments of the disclosure, the trench 504 may be formed to a depth of at least one half (50%) of the desired final thickness of the respective dice 404.

After the trenches 504 are formed along the streets 406 of the wafer 402, a diffusion barrier 604 may be applied over the surfaces of the wafer 402, as illustrated in FIG. 6. The diffusion barrier 604 may be a material configured to substantially prevent diffusion of another material into the wafer 402. For example, a material such as a nitride (e.g., silicon nitride, tantalum nitride), tantalum, etc., may substantially prevent a material such as copper applied to surfaces of the trench from diffusing into the semiconductor material of the wafer 402. In some embodiments, the diffusion barrier 604 may be optional. For example, some materials, such as titanium, may not diffuse into the material of the wafer 402, such that the diffusion barrier 604 may not be necessary to prevent diffusion of such a material into the wafer 402.

The diffusion barrier 604 may be applied through a process, such as a chemical vapor deposition (CVD) process, electroless plating, or sputtering configured to produce a thin and substantially even layer of material. The diffusion barrier 604 may be applied in a substantially even layer over all exposed surfaces of the wafer 402. For example, the diffusion barrier 604 may be applied over the active surface 408 of the wafer 402 and over the surfaces of the trenches 504 including side surfaces 602 of the trenches 504. The diffusion barrier 604 may be applied with a thickness of between about 200 nm and about 2 μm.

After the diffusion barrier 604 is applied over the wafer 402 a conductive layer 702 may be applied over the diffusion barrier 604, as illustrated in FIG. 7. The conductive layer 702 may be formed from an electrically conductive material, such as a metal (e.g., copper, tungsten, titanium, etc.). The conductive material of the conductive layer 702 may be a material configured to generate heat through resistance heating when an electrical current is applied through the conductive layer 702.

As described above, in some embodiments, the conductive layer 702 may be applied directly over the wafer 402, without the intervening diffusion barrier 604, when the conductive layer 702 is formed from a material with a low risk of diffusion into the semiconductor material of the wafer 402. For example, when a material, such as titanium, cobalt, ruthenium, tantalum, tantalum nitride, indium oxide, tungsten nitride, titanium nitride, etc., is applied over the surfaces of the wafer 402, the material may not diffuse into the semiconductor material of the wafer 402. Therefore, such conductive materials may be applied directly over the wafer 402 without the diffusion barrier 604.

Similar to the diffusion barrier 604, the conductive layer 702 may be applied through a process, such as CVD, electroless plating or sputtering configured to produce a thin and substantially even layer of material. The conductive layer 702 may be applied in a substantially even layer over all exposed surfaces of the diffusion barrier 604 and/or wafer 402. For example, the conductive layer 702 may be applied over the active surface 408 of the wafer 402 and over the surfaces of the trenches 504 including side surfaces 602 of the trenches 504. The conductive layer 702 may be applied with a thickness of between about 500 Å and about 1 μm, such as between about 500 Å and about 2000 Å.

The conductive layer 702 alone or the conductive layer 702 combined with the diffusion barrier 604 may form conduction layers 704. The conduction layers 704 discussed herein may include one or both of the conductive layer 702 and the diffusion barrier 604.

After the conductive layer 702 is formed over the surfaces of the wafer 402 and/or diffusion barrier 604, the conduction layers 704 may be removed from the horizontal surfaces of the wafer 402, through a directional material removal process as illustrated in FIG. 8. The directional material removal process may be a process, such as a dry etching process (e.g., reactive-ion etching).

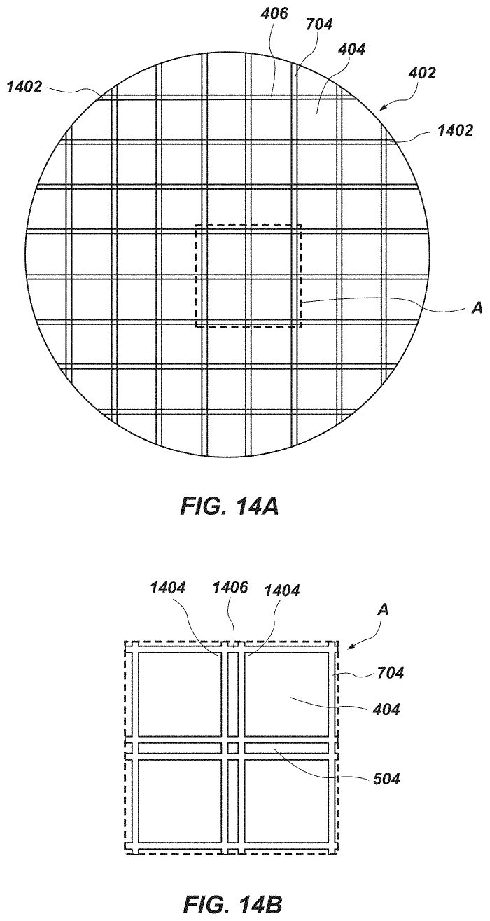

The material removal process may remove the conduction layers 704 from horizontal surfaces, such as the active surfaces 408 and the bottom surfaces 802 of the trenches 504, while leaving the conduction layers 704 on the vertical surfaces, such as the side surfaces 602 of the trenches 504. Thus, the active surface 408 of the wafer 402 and the bottom surfaces 802 of the trenches 504 in the streets 406 may be substantially free of the conduction layers 704. The conductive layer 702 may be electrically connected between the adjacent dice 404 along the vertical side surfaces 602 of the trenches 504 by forming a grid pattern connecting the corners of adjacent dice 404 by spanning the trenches 504 between the corners of the adjacent dice 404 as described in further detail in FIGS. 14A and 14B.

As described above with respect to FIG. 5, dry etching processes may be configured to remove material at a specified rate. The specified rate may be defined by the type of ions used, the material being removed, the temperature of the material, the ambient temperature, etc. Thus, the amount of material removed may be defined by the amount of time that the wafer 402 is subjected to the dry etching process. The time may be defined by the amount of time necessary to remove the conduction layers 704 including the conductive layer 702 and/or diffusion barrier 604 without removing additional material from the active surface 408 of the wafer 402. The amount of time that the wafer 402 is subjected to the material removal process may be insufficient to remove the material from the side surfaces 602 of the trenches 504 due to the directional nature of the material removal process.

In embodiments, the material removal process and/or properties of the material removal process, such as the type of ions used, temperature, etc., may be selected to effectively remove the materials of the conduction layers 704 without substantially damaging or removing material of the active surface 408 of the wafer 402.

In some embodiments, rather than removing materials of the conduction layers with an etching process, a polishing process, such as chemical mechanical planarization (CMP) may be employed to remove such materials from over the active surface 408 of the wafer 402 without removing those materials from the bottoms of trenches 504. As will be appreciated from the description below, such an approach may facilitate conduction of current from a heater across and through the wafer 402.

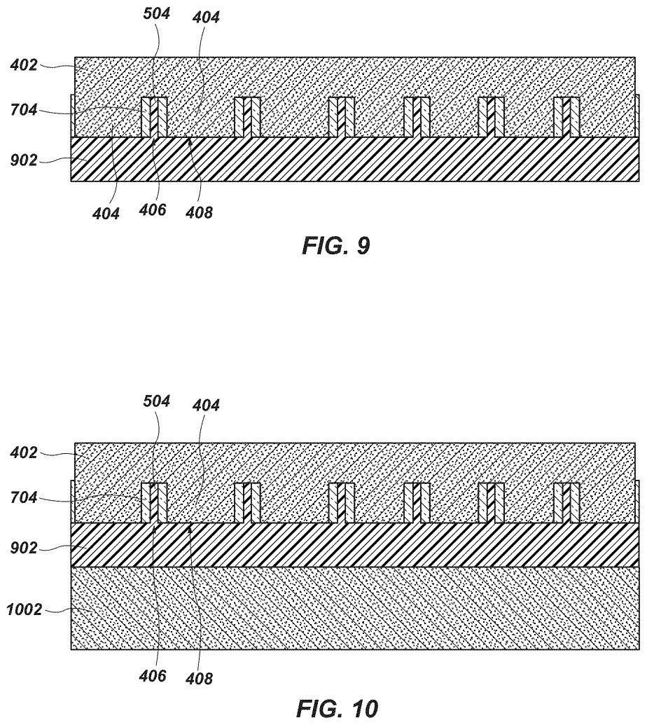

After the conduction layers 704 are removed from the active surface 408 of the wafer 402, an adhesive 902 may be applied over the active surface 408 of the wafer 402 as illustrated in FIG. 9. The adhesive 902 may be a carrier adhesive configured to temporarily bond the wafer 402 to a temporary carrier wafer. The adhesive 902 may be a heat curable adhesive, such as a thermoset adhesive, or a UV curable adhesive. In some embodiments, the adhesive 902 may be water or solvent soluble.

In some embodiments, the adhesive 902 may also substantially fill the trenches 504 in the streets 406 between the dice 404. In other embodiments, the adhesive 902 may only partially fill the trenches 504, such that voids (e.g., air pockets, gas pockets, etc.) within the trenches 504 remain substantially free from the adhesive 902. In other embodiments, the trenches 504 may be substantially free of the adhesive 902, such that the adhesive 902 may not fill the trenches 504 to any substantial extent when applied over the active surface 408 of the wafer 402.

The wafer 402 may then be coupled to a carrier wafer 1002 with the adhesive 902 as illustrated in FIG. 10. The carrier wafer 1002 may be configured to provide structural support to the wafer 402 during additional manufacturing processes, such as thinning by back grinding, polishing, etching, etc. As described above, the adhesive connection between the carrier wafer 1002 and the wafer 402 may be a temporary connection configured to be released, such as through a chemical release, thermal release, etc., after the additional manufacturing processes.

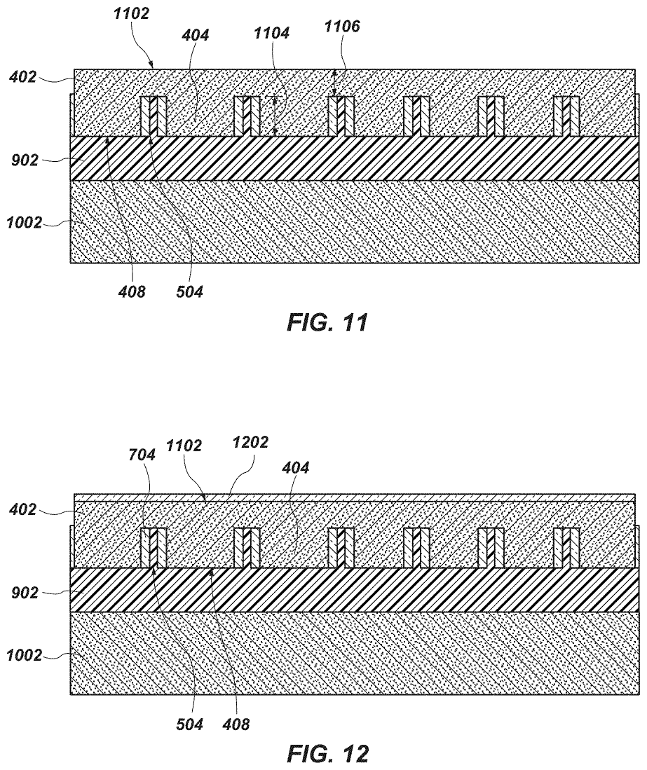

The wafer 402 may be thinned from a back side 1102 of the wafer 402 after being coupled to the carrier wafer 1002 as illustrated in FIG. 11. In some embodiments, the wafer 402 may be thinned through a mechanical process, such as back grinding or polishing, a chemical process, such as chemical etching (e.g., wet etching, dry etching, etc.), a combined chemical mechanical process, such as chemical-mechanical polishing (CMP), silicon CMP, or a combination of multiple different processes. The wafer 402 may be thinned from an initial thickness of, for example, between about 600 μm and about 700 μm to an ultimate thickness of about 50 μm or less.

In some embodiments, the wafer 402 may include vias (not shown), commonly termed through-silicon vias (TSVs), extending through the dice 404 from integrated circuitry over the active surface 408 of each die 404 into the semiconductor material of the wafer 402. The thinning process may be configured to thin the wafer 402 until the vias are exposed through the back side 1102 of the wafer 402. The vias may extend a greater distance from the active surface 408 of the wafer 402 than a depth 1104 of the trenches 504, such that the thinning process may expose the vias before reaching the bottom surfaces 802 of trenches 504. As a result, the dice 404 remain a part of, and connected to, the wafer 402 through a portion of the thickness of wafer 402 between the bottom surfaces 802 of the trenches 504 and the back side 1102 of the wafer 402.

A thickness 1106 of the portion of the wafer 402 between the bottom surfaces 802 of the trenches 504 and the back side 1102 of the wafer 402 may be less than or equal to the depth 1104 of the trenches 504. Therefore, the depth 1104 of the trenches 504 may be at least 50% of the final thickness of the thinned wafer 402.

Once the wafer 402 is thinned to the desired thickness, a passivation layer 1202 may be applied over the back side 1102 of the wafer 402 as illustrated in FIG. 12. The passivation layer 1202 may be formed from an insulating material, such as nitride (e.g., silicon nitride (SiN) or silicon oxynitride (SiON), etc.) or an oxide (e.g., silicon oxide (SiO₂), titanium oxide (TiO), etc.).

After the passivation layer 1202 is formed portions of the passivation layer 1202 may be selectively removed, such as through an etching process, CMP process, etc. The portions of the passivation layer 1202 may be removed to expose connecting features, such as TSVs, pads, etc. In some embodiments, additional process steps may be carried out after the formation of the passivation layer 1202. For example, connecting structures, such as under-bump metallization (UBM) structures, terminal pads, solder bumps, etc., may be formed through the removed portions of the passivation layer 1202.

Some embodiments of the present disclosure may include a wafer processing tool. The tool may include a wafer support and a heater. The heater may include a positive electrical contact configured to interface with a lateral side of a wafer. The heater may also include a negative electrical contact configured to interface with an opposite lateral side of the wafer. The positive electrical contact and the negative electrical contact may be configured to heat streets of the wafer by inducing a current through conductive paths formed in the streets of the wafer.

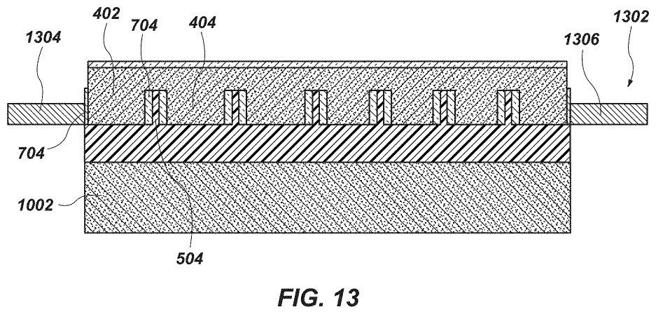

After the wafer 402 is thinned and the passivation layer 1202 is formed over the back side 1102 of the wafer 402, the wafer 402 may be heated as illustrated in FIG. 13. While the wafer 402 is supported by the carrier wafer 1002, a heater 1302. For example a resistance heater, may be placed in contact with the wafer 402 to heat the wafer 402. The heater 1302 may be configured to heat the wafer 402 to a temperature greater than about 100° C., such as between about 120° C. and about 300° C., or between about 150° C. and about 200° C. The heat may be transferred through the wafer 402 by the conduction layers 704 formed in the trenches 504, which trenches 504 may be formed to extend to side surfaces of wafer 402.

The heater 1302 may heat the wafer 402 by transmitting an electrical current through the conduction layers 704 between a first heater contact 1304 and a second heater contact 1306. For example, the first heater contact 1304 may be a positive electrical contact and the second heater contact 1306 may be a negative electrical contact of a direct current (DC) source. The first heater contact 1304 may be connected to the second heater contact 1306 through a path created by the conduction layers 704, such that the first heater contact 1304 and the second heater contact 1306 may transmit an electrical current through the conduction layers 704 from the first heater contact 1304 to the second heater contact 1306, heating the wafer 402.

In some embodiments, the heater 1302 may include multiple pairs of heater contacts 1304, 1306. For example, the heater 1302 may include at least four heater contacts 1304, 1306, including at least two positive electrical source contacts and at least two negative electrical source contacts. The heater contacts 1304, 1306 may be positioned within the heater 1302, such that the heater contacts 1304, 1306 will be spaced radially about the wafer 402 when in contact with the wafer 402.

FIGS. 14A and 14B, illustrate a top view of the wafer 402 illustrating the conduction layers 704 surrounding the dice 404. FIG. 14B illustrates an enlarged view of section A of the wafer 402. The wafer 402 may include exposed portions 1402 of the conduction layers 704, where the conduction layers 704 are exposed about the perimeter of the wafer 402 in areas substantially aligned with the streets 406 between the dice 404. In some embodiments, the exposed portion 1402 may include pads, or a metal seed layer about the edge of the wafer 402 configured to create a larger connecting surface in the exposed portions 1402 for connecting to the heater contacts 1304, 1306. The conduction layers 704 may form a grid pattern through the active surface 408 of the wafer 402 with connections 1406 spanning the trenches 504 between the corners 1404 of adjacent dice 404.

The connections 1406 may be formed by vertical walls of the conduction layers 704 that may be formed when the diffusion barrier 604 and/or conductive layer 702 of the conduction layers 704 are formed. The vertical walls of the conduction layers 704 in the connections 1406 may survive the material removal process illustrated FIG. 8 for substantially the same reasons described above, with respect to FIG. 8. For example, the amount of time that the wafer 402 is subjected to the material removal process may be insufficient to remove the material from the vertical walls of the conduction layers 704 due to the directional nature of the material removal process. As described above, the conduction layers 704 may be removed from the horizontal surfaces of the trenches 504 between the dice 404, such that the vertical walls of the conduction layers 704 forming the connections 1406 may be the only remaining connections between the conduction layers 704 of adjacent dice 404.

The connections 1406 may enable electrical connectivity between the conduction layers 704 on the side surfaces 602 of the trenches 504 between the dice 404. The electrical connectivity between the conduction layers 704 may form an electrically conductive grid pattern through the active surface 408 of the wafer 402. The grid pattern formed by the conduction layers 704 may create an electrically conductive path between exposed portions 1402 of the conduction layers 704. The heater 1302 may be configured to contact one or more of the exposed portions 1402 of the conduction layers 704 with the first heater contact 1304 and another one or more of the exposed portions 1402 of the conduction layers 704 with the second heater contact 1306.

As described above, the heater 1302 may transmit an electrical current through the grid pattern of the conduction layers 704 between the first heater contact 1304 and the second heater contact 1306. The electrical current passing through the conduction layers 704 may generate heat. The heat in the conduction layers 704 may then be transferred to the semiconductor material of wafer 402 through thermal conduction.

As described above, the heater 1302 may include multiple sets of heater contacts 1304, 1306 positioned radially about the wafer 402. The multiple sets of heater contacts 1304, 1306 may generate multiple different electrical currents in the grid of conduction layers 704. For example, each set of heater contacts 1304, 1306 may generate an electrical current in the section of the wafer 402 between the set of heater contacts 1304, 1306. The multiple electrical currents may generate heat in each respective section of the wafer 402. Thus, the heat generated by the multiple electrical currents may be distributed throughout the wafer 402, such that the wafer 402 may be heated in a substantially even manner, wherein temperature differentials between different sections of the wafer 402 may be reduced during the heating process. Heating the wafer 402 in a substantially even manner may reduce the time required to raise the temperature of the wafer 402 to the desired temperature.

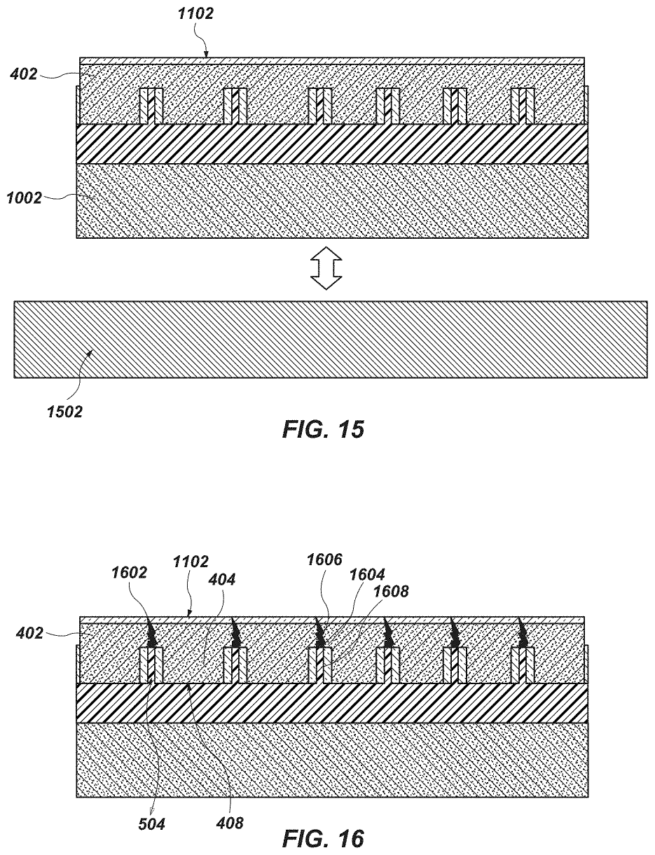

Once the wafer 402 is heated to the desired temperature, the wafer 402 may be rapidly cooled as illustrated in FIG. 15. The wafer 402 may be rapidly cooled using a cooling element 1502. The cooling element 1502 may be configured to rapidly reduce the temperature of the wafer 402 by between about 100° C. and about 200° C., such as between about 100° and about 150° C. For example, the cooling element 1502 may be maintained at a temperature of at least about 100° less than the temperature of the heated wafer 402, such that the heat of the wafer 402 may be rapidly absorbed by the cooling element 1502. In some embodiments, the temperature of the cooling element 1502 may be maintained at a temperature below the desired temperature of the wafer 402. For example, if the cooling element 1502 is configured to cool the wafer 402 by 100° C., the cooling element 1502 may be maintained at a temperature at least 110° C. less than the temperature of the heated wafer 402, such as at least about 120° C. less than the temperature of the heated wafer 402, at least about 150° C. less than the temperature of the heated wafer 402, or at least about 210° C. less than the temperature of the heated wafer 402.

In some embodiments, the cooling element 1502 may be a chilled surface, such as a cold plate, cold chuck, etc. The carrier wafer 1002 may be placed on and/or secured to the chilled surface. The chilled surface may be maintained at a temperature substantially lower than the temperature of the heated wafer 402, such that the heat may be rapidly removed from the wafer 402 and absorbed by the chilled surface. In some embodiments, the chilled surface may absorb the heat from the heated wafer 402 through thermal conduction through the carrier wafer 1002. In some embodiments, the wafer 402 may be placed directly on the chilled surface. For example, the back side 1102 of the wafer 402 may be placed on the chilled surface, such that the wafer 402 is positioned between the carrier wafer 1002 and the chilled surface. In some embodiments, the cooling element 1502 may include multiple chilled surfaces. For example, a chilled surface may be placed on both the carrier wafer 1002 and the back side 1102 of the wafer 402, such that the wafer 402 and carrier wafer 1002 are sandwiched between the two cold surfaces.

The chilled surface may be cooled through an external cooling element. For example, a cooling fluid, such as a refrigerant, water, etc., may flow through channels adjacent the chilled surface to remove heat from the chilled surface. The cooling fluid may then pass through a heat exchanger that may remove the heat from the cooling fluid. For example, the heat may be removed through a refrigeration cycle (e.g., reverse Carnot cycle). Thus, the cooling fluid may maintain the chilled surface at the desired low temperature while the chilled surface absorbs the heat from the wafer 402.

In some embodiments, the cooling element 1502 may be cold bath, such as a cold de-ionized (DI) water bath. The wafer 402 may be at least partially submerged in the cold bath, such that the cold fluid may substantially surround the wafer 402 and/or the carrier wafer 1002. The surrounding cold fluid may be configured to rapidly absorb the heat from the wafer 402. The fluid in the bath may be cooled through a heat exchanger system in a similar manner to that described above for the cooling fluid of a chilled surface, such that the fluid in the bath may be maintained an the low temperature while absorbing the heat from the wafer 402.

The rapid cooling of the wafer 402 may induce thermoshock within the wafer 402 as illustrated in FIG. 16. The thermoshock may cause the wafer 402 to rapidly contract and may induce fractures 1602 at weak points in the wafer 402. The trenches 504 may create stress concentrations such that the thermoshock may cause the fractures 1602 to be created through the wafer 402 in a position substantially aligned with the trenches 504. The fractures 1602 may substantially separate the individual dice 404 along the streets 406.

Some embodiments of the present disclosure may include microelectronic devices. The microelectronic devices may include an active surface and a side surface. The side surface may include a first portion having a reflective surface and a second portion having a non-reflective surface. The first portion may cover at least 50% of the side surface.

After the individual dice 404 are separated by the fractures 1602, side surfaces 1604 of the individual dice 404 may include a smooth surface 1608 characterized by a reflective, clear, or mirror finish and a rough surface 1606 (e.g., uneven surface) characterized by a non-reflective or matte finish. The conduction layers 704 on the side surfaces 1604 of the dice 404 may provide the smooth, reflective surface 1608. As described above, the conduction layers 704 may extend at least about 50% of the thickness of the finished thickness of the dice 404. Therefore, the conduction layers 704 may cover at least about 50% of the side surfaces 1604 of the dice 404. Accordingly, the rough surface 1606 may be no more than about 50% of the side surfaces 1604 of the dice 404. The rough surfaces 1606 may be associated with the portion of the dice 404 associated with the fractures 1602. The fractures 1602 may produce a rough surface 1606 having multiple ridges and/or valleys reducing the reflective qualities of the rough surface 1606.

The fractures 1602 may be substantially clean, such that substantially no loose particles are produced by the fractures 1602. For example, the fractures 1602 may produce substantially complementary rough surfaces on adjacent dice 404, such that material of the wafer 402 between the adjacent dice 404 is substantially present on either the first die 404 or the second die 404 with no particles of wafer material being dislodged when the dice 404 are separated by the thermoshock fracture 1602. Reducing the number of particles of wafer material produced when separating the dice 404 may reduce the number of particles present on surfaces of the dice 404 that may cause later failures.

After the fractures 1602 are formed along the streets 406 of the wafer 402, the separated dice 404 may be picked from the carrier wafer 1002 in a picking process. In some embodiments, the picking process may introduce elements configured to release the adhesive 902, such as a solvent configured to chemically release or dissolve the adhesive 902 or a laser configured to thermally release the adhesive 902. For example, the dice 404 may be cleaned with a nozzle before the picking tool picks the dice 404 form the surface of wafer 402. The nozzle may introduce a solvent over the surfaces of the dice 404. The solvent may flow into the streets 406 between the dice 404 through the fractures 1602 and the trenches 504, such that the solvent may contact and dissolve the adhesive 902.

In some cases, an inspection may be performed on the wafer 402 after fracturing the wafer 402 and before picking the dice 404 from the carrier wafer 1002 to determine if the fractures 1602 are sufficient to separate the dice 404. For example, the wafer 402 may be inspected using infrared radiation (IR) to confirm that the fractures 1602 pass completely through the wafer 402 along the streets 406.

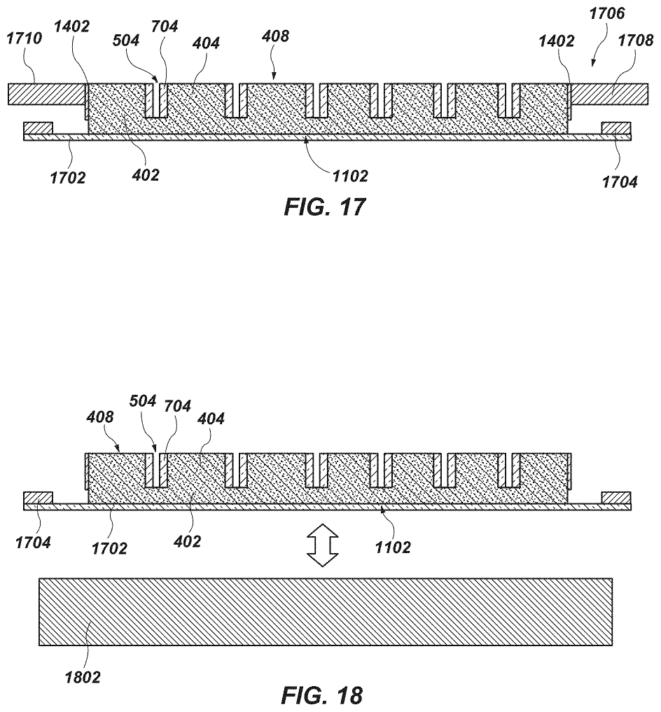

In some embodiments, the wafer 402 may be debonded from the carrier wafer 1002 before heating the wafer 402 as illustrated in FIGS. 17 and 18. After the wafer 402 has been thinned to the final thickness and the passivation layer 1202 has been applied, the adhesive 902 may be released, such as through a thermal release or a chemical release disconnecting the active surface 408 of the wafer 402 from the carrier wafer 1002. The wafer 402 may then be removed from the carrier wafer 1002. The back side 1102 of the wafer 402 may then be coupled to a carrier material 1702 supported by a film frame 1704.

The carrier material 1702 and the film frame 1704 may be configured to support the wafer 402 during the heating and cooling processes described above. The carrier material 1702 may include an adhesive securing the back side 1102 of the wafer 402 to the carrier material 1702. The carrier material 1702 may be a material, such as mount tape or dicing tape.

As described above, a heater 1706 may be placed in contact with the wafer 402 to heat the wafer 402. The heat may be transferred through the wafer 402 by the conduction layers 704 formed in the trenches 504. The heater 1706 may heat the wafer 402 by transmitting an electrical current through the conduction layers 704 between a first heater contact 1708 and a second heater contact 1710. For example, the first heater contact 1708 may be a positive contact and the second heater contact 1710 may be a negative contact of a direct current (DC) source. The first heater contact 1708 may be connected to the second heater contact 1710 through a path created by the conduction layers 704, such that the first heater contact 1708 and the second heater contact 1710 may induce an electrical current through the conduction layers 704 from the first heater contact 1708 to the second heater contact 1710.

As described above, the wafer 402 may include exposed portions 1402 of the conduction layers 704, where the conduction layers 704 about the perimeter of the wafer 402 are exposed in areas substantially aligned with the streets 406 (FIGS. 14A, 14B) between the dice 404. The conduction layers 704 may form a grid pattern through the active surface 408 of the wafer 402 with connections 1406 between the corners 1404 of adjacent dice 404 (FIGS. 14A, 14B).

The heater 1706 may be configured to contact one or more of the exposed portions 1402 of the conduction layers 704 with the first heater contact 1708 and another one or more of the exposed portions 1402 of the conduction layers 704 with the second heater contact 1710.

As described above, the heater 1302 may transmit an electrical current through the grid pattern of the conduction layers 704 through the first heater contact 1708 and the second heater contact 1710. The electrical current passing through the conduction layers 704 may generate heat. The heat in the conduction layers 704 may then be transferred to the wafer 402 through thermal conduction.

As described above, the heater 1706 may include multiple sets of heater contacts 1708, 1710 positioned radially about the wafer 402. The multiple sets of heater contacts 1708, 1710 may generate multiple different electrical currents in the grid of conduction layers 704. For example, each set of heater contacts 1708, 1710 may generate an electrical current in the section of the wafer 402 between the set of heater contacts 1708, 1710. The multiple electrical currents may generate heat in each respective section of the wafer 402. Thus, the heat generated by the multiple electrical currents may be distributed throughout the wafer 402, such that the wafer 402 may be heated in a substantially even manner, wherein temperature differentials between different sections of the wafer 402 may be reduced during the heating process. Heating the wafer 402 in a substantially even manner may reduce the time required to raise the temperature of the wafer 402 to the desired temperature.

Once the wafer 402 is heated to the desired temperature, the wafer 402 may be rapidly cooled as illustrated in FIG. 18. The wafer 402 may be rapidly cooled using a cooling element 1802. As described above, the cooling element 1802 may be configured to rapidly reduce the temperature of the wafer 402 by between about 100° C. and about 200° C., such as between about 100° and about 150° C. The cooling element 1802 may be maintained at a temperature of at least about 100° less than the temperature of the heated wafer 402, such that the heat of the wafer 402 may be rapidly absorbed by the cooling element 1802. As described above, the temperature of the cooling element 1802 may be maintained at a temperature below the desired temperature of the wafer 402.

In some embodiments, the cooling element 1802 may be a chilled surface, such as a cold plate, cold chuck, etc. The carrier material 1702 and film frame 1704 may be placed on and/or secured to the chilled surface. The chilled surface may be maintained at a temperature substantially lower than the temperature of the heated wafer 402, such that the heat may be rapidly removed from the wafer 402 and absorbed by the chilled surface. The chilled surface may absorb the heat from the heated wafer 402 through thermal conduction through the carrier material 1702. The carrier material 1702 may be relatively thin such that the carrier material 1702 may enable efficient heat transfer from the wafer 402 to the cooling element 1802.

As described above, the chilled surface may be cooled through a cooling fluid, such as refrigerant, water, etc., that may flow through channels in the cooling element 1802 adjacent the chilled surface removing heat from the chilled surface. The cooling fluid may then pass through a heat exchanger that may remove the heat from the cooling fluid, such as through a refrigeration cycle (e.g., reverse Carnot cycle). Thus, the cooling fluid may maintain the chilled surface at the desired low temperature while the chilled surface absorbs the heat from the wafer 402.

In some embodiments, the cooling element 1802 may be cold bath, such as a cold de-ionized (DI) water bath. The wafer 402 may be at least partially submersed in the cold bath, such that the cold fluid may substantially surround the wafer 402. The surrounding cold fluid may be configured to rapidly absorb the heat from the wafer 402. The fluid in the bath may be cooled through a heat exchanger system in a similar manner to that described above for the cooling fluid of a chilled surface, such that the fluid may be maintained at the cold temperature while absorbing heat from the wafer 402.

The rapid cooling of the wafer 402 may induce thermoshock within the wafer 402 as illustrated above in FIG. 16. The thermoshock may cause the wafer 402 to rapidly contract and may induce fractures 1602 at weak points in the wafer 402. The trenches 504 may create stress concentrations such that the thermoshock may cause the fractures 1602 to be created through the wafer 402 in a position substantially aligned with the trenches 504. The fractures 1602 may substantially separate the individual dice 404 along the streets 406.

After the fractures 1602 are formed along the streets 406 of the wafer 402, the separated dice 404 may be picked from the carrier material 1702 in a picking process. In some embodiments, the picking process may introduce elements configured to release the adhesive between the wafer 402 and the carrier material 1702, such as a solvent configured to chemically release or dissolve the adhesive or a laser configured to thermally release the adhesive. For example, the dice 404 may be cleaned with a nozzle before the picking tool picks the dice 404 form the surface of wafer 402. The nozzle may introduce a solvent over the surfaces of the dice 404. The solvent may flow into the streets 406 between the dice 404 through the fractures 1602 and the trenches 504, such that the solvent may contact and dissolve the adhesive. In other embodiments, a laser may be directed to an opposite side of the carrier material 1702 from the wafer 402 to heat the adhesive on the carrier material 1702 thermally releasing the adhesive before picking the dice 404 from the carrier material 1702.

In some cases, before picking the dice 404 from the carrier material 1702, the carrier material 1702 may be stretched radially by the film frame 1704. Stretching the carrier material 1702 may increase the separation between the dice 404 along the streets 406 where the trenches 504 and fractures 1602 have separated the wafer 402 into individual dice 404. Stretching the carrier material 1702 may complete the separation of the dice 404 where small amounts of wafer 402 or conduction layers 704 remain connected, such that the small amounts of wafer 402 and/or conduction layers 704 may not interfere with the picking process.

In some cases, an inspection may be performed on the wafer 402 after fracturing the wafer 402 and before picking the dice 404 from the carrier material 1702 to determine if the fractures 1602 are sufficient to separate the dice 404. For example, the wafer 402 may be inspected using (IR) to confirm that the fractures 1602 pass completely through the wafer 402 along the streets 406. In another example, light may be used to determine if the fracture 1602 pass completely through the wafer 402. Light may be directed on an opposite side of the carrier material 1702 from the wafer 402, such that light shines on the back side 1102 of the wafer 402. When viewed on the side of the 402 corresponding to the active surface 408 of the wafer 402, the light may shine through the wafer 402 with greater intensity along the streets 406 where the fractures 1602 have completely passed through the wafer 402.

Some embodiments of the present disclosure may include a microelectronic device package. The microelectronic device package may include a microelectronic device including an active surface and a side surface. The side surface may include a first portion having a reflective surface and a second portion having a non-reflective surface.

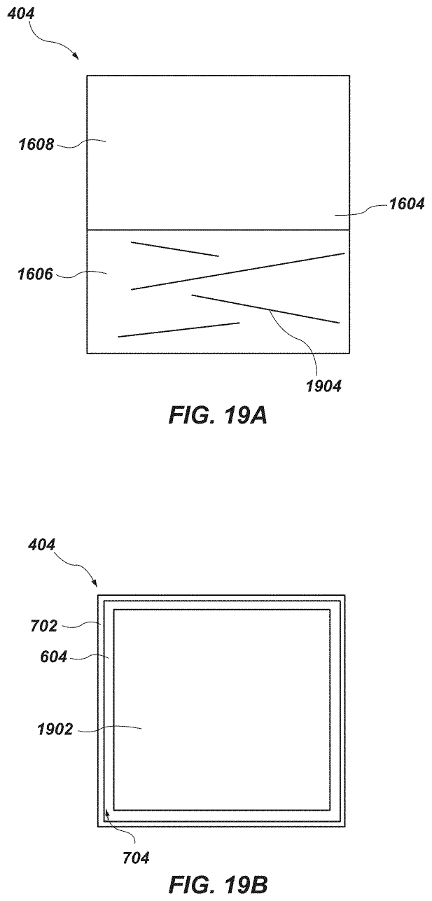

FIGS. 19A and 19B are views of a die 404 after being singulated and picked from the wafer 402. FIG. 19A is a side view of the die 404 illustrating the side surface 1604 of the die 404. As described above, the side surface 1604 may include a smooth surface 1608 and a rough surface 1606. The smooth surface 1608 may be characterized by a reflective or mirror finish. The smooth surface 1608 may be the outer surface of the conductive layer 702. The reflective or mirror finish may be a result of the outer surface of the conductive layer 702 being substantially untouched by other processing steps, such as blade dicing, wet etching, etc. The rough surface 1606 may be characterized by a non-reflective or matte finish. The non-reflective or matte finish may be a result of the uneven surface of the fracture 1602 formed by thermoshock as described above. The uneven surface may include multiple jagged features 1904, such as ridges, valleys, non-planar surfaces, intersecting planes, striations, etc.

As described above, the conduction layers 704 may cover at least 50% of the thickness of the side surface 1604 of the die 404. Therefore, the smooth surface 1608 may comprise at least 50% of the side surface 1604, with the rough surface 1606 covering the remaining portion of the side surface 1604.

FIG. 19B illustrates a top view of the die 404. The top of the die 404 may have an active surface 1902 that may include conductive elements, integrated circuitry elements, microelectronic elements, connections, etc. The conduction layers 704 may be formed about a perimeter of a top portion of the die 404. As described above, the conduction layers 704 may include the conductive layer 702 and an optional diffusion barrier 604. For example, the conductive layer 702 may be superimposed over the diffusion barrier 604. In some embodiments, the conduction layers 704 may include the conductive layer 702 formed about the perimeter of the top portion of the die 404 without the diffusion barrier 604 formed between the conductive layer 702 and the die 404.

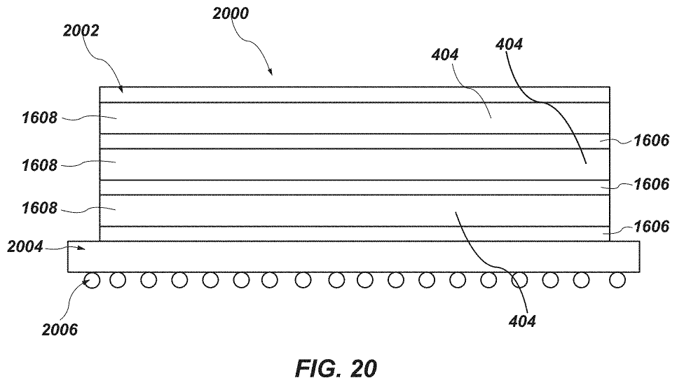

FIG. 20 illustrates a microelectronic device 2000 formed from a stack of dice 404. The microelectronic device 2000 may include a cap layer 2002 applied over a top die 404. The sides of the stack of die 404 may be characterized by a pattern of alternating smooth surfaces 1608 and rough surfaces 1606. Because the smooth surfaces 1608 each cover at least 50% of each die 404, the smooth surfaces 1608 may similarly cover at least 50% of the side surfaces of the stack of dice 404.

The dice 404 may be stacked over a substrate 2004 configured to electrically couple the stack of dice 404 to another component. The substrate 2004 may include solder bumps 2006 configured to connect to another component. The substrate 2004 may be electrically coupled to the stack of dice 404, such as through the TSVs formed through each die 404. Similarly, each die 404 may be electrically coupled to the adjacent dice 404 through the TSVs. In some embodiments, the dice 404 may include additional, contact pads, UBMs, solder bumps, etc., configured to couple the TSVs of adjacent dice 404.

In some embodiments, the cap layer 2002 may be formed from a metal material. The cap layer 2002 may be coupled to the conductive layer 702 of the smooth surface 1608, such that the top portion of the top die 404 of the stack of dice 404 may be substantially surrounded by the metal material of the cap layer 2002 and the conductive layer 702. The surrounding metal material may provide protection against electromagnetic interference (EMI) for at least the top die 404 of the stack of dice 404 and may facilitate the formation of a Faraday cage about the entire stack of dice 404.

Microelectronic devices singulated according to embodiments of the disclosure may, by formation of metal (e.g., copper) jackets about the periphery of each die provide an optical means, due to the reflective nature of the metal jackets, of verifying bondline thickness (BLT) and uniformity of same between adjacent dice in a stacked assembly. The metal jacket further provides protection against electromagnetic interference (EMI) with the integrated circuitry of a die, and allows fabrication of a Faraday cage about a stack of such dice by the addition of a metal material over a top of a die stack.

Embodiments of the present disclosure may substantially decrease the number of particles produced during the process of dicing or singulating individual dice from a wafer. Particles on individual semiconductor dice may cause damage and/or failures in associated microelectronic devices. Thus, reducing the particles produced during the dicing or singulation process may similarly decrease the damage or failures of the dice and associated microelectronic devices. Embodiments of the present disclosure may further enable the space (i.e., street width) between semiconductor devices to be reduced by reducing the width of spaces required to singulate the wafer, increasing the number of dice per wafer which may be fabricated. Reducing the number of damaged or failed dice or microelectronic devices and decreasing the space required between the individual dice on each wafer may increase the yield of dice and microelectronic devices.

Increasing the yield of microelectronic devices by reducing the number of damaged semiconductor devices or microelectronic device stacks rendered useless may increase the yield of the production of microelectronic devices. Increased yield may result in greater profitability or reduced costs for the production of the associated microelectronic devices, as well as improved device longevity in service. The microelectronic devices may be included in multiple different types of electronic devices, such as personal electronics (e.g., mobile devices, phones, tablets, etc.), computers (e.g., personal computers, laptops, etc.), etc. Reducing the cost of producing the microelectronic devices may in turn reduce the cost of producing the associated electronic devices.

The embodiments of the disclosure described above and illustrated in the accompanying drawing figures do not limit the scope of the invention, since these embodiments are merely examples of embodiments of the invention, which is defined by the appended claims and their legal equivalents. Any equivalent embodiments are intended to be within the scope of this disclosure. Indeed, various modifications of the present disclosure, in addition to those shown and described herein, such as alternative useful combinations of the elements described, may become apparent to those skilled in the art from the description. Such modifications and embodiments are also intended to fall within the scope of the appended claims and their legal equivalents.

What is claimed is:

1. A microelectronic device comprising:
an active surface;
a side surface including:
a first portion having a reflective surface, wherein the first portion comprises at least about 50% of the side surface; and
a second, longitudinally adjacent portion having a non-reflective surface.

2. The microelectronic device of claim 1, wherein the reflective surface comprises a metal material.

3. The microelectronic device of claim 2, wherein the metal material is selected from the group consisting of copper, tungsten, and titanium.

4. The microelectronic device of claim 1, wherein the reflective surface comprises an electrically conductive material.

5. The microelectronic device of claim 1, wherein the non-reflective surface comprises a fractured surface of semiconductor material.

6. The microelectronic device of claim 1, wherein the first portion includes two superimposed materials.

7. The microelectronic device of claim 6, wherein the two superimposed materials include a diffusion barrier adjacent a semiconductor material of and a conductive material over the diffusion barrier.

8. The microelectronic device of claim 7, wherein the diffusion barrier comprises a material selected from a group consisting of nitride, silicon nitride, tantalum, tantalum nitride.

9. The microelectronic device of claim 7, wherein the conductive material comprises a metal.

10. The microelectronic device of claim 7, wherein the conductive material comprises a material selected from the group consisting of copper, tungsten, titanium.

11. A method of manufacturing a microelectronic device comprising:
forming one or more microelectronic devices on an active surface of a wafer;
removing material from the wafer in streets between the one or more microelectronic devices to form trenches in the streets;
depositing a metal material on sides of the trenches in the streets;
heating the metal material on the sides of the trenches in the streets;
cooling the wafer after heating the metal material; and
fracturing the wafer along the streets through thermoshock induced by cooling the wafer.

12. The method of claim 11, wherein heating the metal material on the sides of the trenches in the streets further comprises transmitting an electrical current through the metal material.

13. The method of claim 11, wherein cooling the wafer comprises cooling the wafer to a temperature at least 100° C. less than a temperature of the wafer after heating the metal material.

14. The method of claim 11, wherein cooling the wafer comprises placing the wafer in contact with a cooling element.

15. The method of claim 14, wherein the cooling element comprises a cold fluid bath.

16. The method of claim 15, wherein the cold fluid bath comprises de-ionized water.

17. The method of claim 14, wherein the cooling element comprises a cold surface.

18. A wafer processing tool comprising:
a wafer support; and
a heater including:
a positive electrical contact configured to interface with a lateral side of a wafer; and
a negative electrical contact configured to interface with an opposite lateral side of the wafer, the positive electrical contact and the negative electrical contact configured to heat streets of the wafer by transmitting a current through conductive paths formed in the streets of the wafer.

19. The wafer processing tool of claim 18, wherein the wafer support comprises a carrier wafer.

20. The wafer processing tool of claim 18, wherein the wafer support comprises a carrier material supported by a film frame.

21. The wafer processing tool of claim 18, further comprising a cooling element.

22. The wafer processing tool of claim 21, the cooling element comprising a cold fluid bath or a cold surface.

23. A microelectronic device package comprising:
a stack of microelectronic devices, each including:
an active surface;
a side surface including:
a first metal portion exhibiting a reflective surface; and
a second portion of semiconductor material exhibiting a non-reflective surface.

24. The microelectronic device package of claim 23, wherein the first metal portion comprises at least about 50% of the side surface.

25. A method of separating microelectronic devices from a wafer, the method comprising:
removing material from the wafer in streets between the microelectronic devices to form trenches in the streets;
depositing a metal material on one or more surfaces of the trenches;
heating the wafer by inducing an electrical current in the metal material on the one or more surfaces of the trenches;
cooling the wafer after heating the wafer; and
fracturing the wafer along the streets through thermoshock induced by cooling the wafer.

26. The method of claim 25, further comprising removing the metal material from horizontal surfaces of the trenches, such that the metal material forms vertical walls alongside surfaces of the trenches spanning the trenches between corners of adjacent microelectronic devices.
